(19) United States
(12) Patent Application Publication
(10) Pub. No.: US 2026/0307177 A1
(43) Pub. Date: Oct. 8, 2026

(54) SINGLE-CRYSTAL DIAMOND MICROCHANNEL WITHOUT INTERNAL MODIFIED AREA, AND MANUFACTURING METHOD THEREOF

(71) Applicant: Xi’an Jiaotong University, Xi'an City (CN)

(72) Inventors: Jianlei CUI, Xi'an City (CN); Haozhe KANG, Xi'an City (CN); Xuesong MEI, Xi'an City (CN); Zhengjie FAN, Xi'an City (CN); Zheng SUN, Xi'an City (CN); Wenjun WANG, Xi'an City (CN); Wanqin ZHAO, Xi'an City (CN); Bin LIU, Xi'an City (CN)

(21) Appl. No.: 19/640,867

(22) Filed: Apr. 7, 2026

(30) Foreign Application Priority Data
Apr. 7, 2025 (CN) 202510426586.6

(51) Int. Cl. B23K 26/55; B23K 26/035; B23K 26/0622; B23K 26/064; B23K 26/082; B23K 26/70; B23K 103/00

(52) U.S. Cl. CPC B23K 26/55; B23K 26/035; B23K 26/0624; B23K 26/0648; B23K 26/082; B23K 26/702; B23K 2103/52

(57) ABSTRACT

Provided are a single-crystal diamond microchannel without an internal modified area, and a manufacturing method thereof. The manufacturing method includes: focusing a laser focus on a preset depth position of a target microchannel, and subjecting a bottom area of a side wall of the microchannel to selective induction to form a modified layer; subjecting the microchannel to layer-by-layer scanning, and processing and forming along a preset microchannel path to form a microchannel; and subjecting a resulting processed and formed microchannel to high-temperature oxidation to remove the modified layer in the microchannel, and cleaning and drying to obtain the diamond microchannel without the internal modified structure.

### CROSS REFERENCE TO RELATED APPLICATION

This patent application claims the benefit and priority of Chinese Patent Application No. 202510426586.6 filed with the China National Intellectual Property Administration on Apr. 7, 2025, and entitled with “SINGLE-CRYSTAL DIAMOND MICROCHANNEL WITHOUT INTERNAL MODIFIED AREA, AND MANUFACTURING METHOD THEREOF”, the disclosure of which is incorporated by reference herein in its entirety as part of the present application.

### TECHNICAL FIELD

The present disclosure belongs to the technical field of laser processing, and in particular, relates to a single-crystal diamond microchannel without an internal modified area, and a manufacturing method thereof.

### BACKGROUND

Single-crystal diamond has become a core material in the fields of precision optics, semiconductor heat dissipation, biosensing, and extreme environment devices due to its ultrahigh hardness (Mohs hardness of 10), superior thermal conductivity (>2000 W/m K), wide-spectrum transparency (from ultraviolet to far infrared), and excellent chemical stability. With the development of micro-nano manufacturing technology, it is increasingly urgent to process a high-quality microchannel structure on a surface of the single-crystal diamond, for example, a fluid channel for a microfluidic chip, a heat-dissipating microstructure of a high-power laser, an optical diffraction element, and a waveguide structure of a quantum device. However, an existing microchannel processing technology for the single-crystal diamond faces significant technical bottlenecks, specifically as follows:

limitation of the processing efficiency: although ion beam etching (such as focusing ion beams) can achieve nano-scale precision, the material removal rate is extremely low, it takes several hours to process a large-depth microchannel (depth>100 µm), and high-energy ion bombardment is prone to cause surface lattice damage; and although chemical-assisted mechanical polishing can achieve non-destructive processing, it is only suitable for a shallow structure (depth<10 µm) and is difficult to meet the deep-groove requirement.

Deterioration of intrinsic properties of materials: when a microchannel is formed by traditional laser processing (such as femtosecond laser and nanosecond laser) through local ablation or phase change, high-temperature thermal effect will lead to damage to a diamond lattice structure, resulting in the generation of an amorphous carbon modified layer on a surface and a subsurface of the microchannel, even the generation of an internal modified area in other areas of a diamond body. These modified areas, particularly the internal modified area that cannot be removed, will significantly deteriorate the thermal conductivity, optical transparency, and mechanical strength of the diamond, thereby limiting the application of the diamond in ultra-precision optics and high-temperature environments.

For the above problems, the industry urgently needs a manufacturing technology for a single-crystal diamond microchannel with no internal damage, large-depth processing ability, high efficiency, and low cost.

### SUMMARY

To solve the problems in the prior art, the present disclosure provides a method for manufacturing a single-crystal diamond microchannel without an internal modified area. Through a pre-embedded modified layer strategy for energy shielding, lattice damage is avoided while achieving precise control of the depth and shape of the microchannel.

To achieve the above objects, the present disclosure adopts the following technical solution: a method for manufacturing a diamond microchannel without an internal modified structure, including:

focusing a laser focus on a preset depth position of a target microchannel, and subjecting a bottom area of a side wall of the microchannel to selective induction to form a modified layer;

subjecting the microchannel to layer-by-layer scanning, and processing and forming along a preset microchannel path to form a microchannel; and

subjecting a resulting processed and formed microchannel to high-temperature oxidation to remove the modified layer in the microchannel, and cleaning and drying to obtain the diamond microchannel without the internal modified structure.

In some embodiments, an ultraviolet picosecond laser processing system is used, and a laser has a central wavelength of 355 nm and a pulse width of 10 ps.

In some embodiments, the ultraviolet picosecond laser processing system is turned on and warmed up, and a position of the laser focus is accurately calibrated with a silicon wafer having a uniform thickness.

In some embodiments, a single-crystal diamond wafer is ultrasonically cleaned with acetone, anhydrous ethanol, and deionized water, and finally dried.

In some embodiments, an error between a focusing position of the laser focus and a position of an actual focus is within ±5 µm.

In some embodiments, the method further comprises conducting a focus offset compensation when the laser focus focuses on the preset depth position of the target microchannel.

In some embodiments, a small single-pulse energy is used, and a scanning speed is matched with a laser repetition frequency, so that an equivalent pulse density is greater than 10/µm; and a scanning path is a periodic jump scanning path, and a transverse interval is 0.2 to 1 times a diameter of the laser focus.

In some embodiments, a large single-pulse energy is used, and a scanning speed is matched with a laser repetition frequency, so that an equivalent pulse density is greater than 50/µm; and a scanning path is a periodic jump scanning path, a transverse interval is 0.2 to 1 times a diameter of the laser focus, a longitudinal interval is in a range of 10 µm to 30 µm, a number of scanning lines in an XY plane is matched with a width of the microchannel, and a number of longitudinal scanning lines is matched with a depth and the longitudinal interval.

In some embodiments, subjecting the resulting processed and formed microchannel to high-temperature oxidation is conducted by vacuumizing a treatment environment, then filling with oxygen, and then conducting heating oxidation.

The present disclosure further provides a diamond microchannel without an internal modified structure, obtained by the above manufacturing method.

Some embodiments of the present disclosure at least have the following beneficial technical effects:

Compared with the prior art, in the present disclosure, the ultraviolet picosecond laser is used to process the single-crystal diamond microchannel, which gives consideration to the precision and efficiency of femtosecond lasers and picosecond lasers, and achieves the efficient processing of the microchannel with a small taper. The single-crystal diamond wafer is placed on a processing stage of an ultraviolet picosecond laser processing system, a laser focus is accurately focused on the preset depth position (that is, the bottom of the final microchannel) of the target microchannel, and the bottom area of the side wall of the microchannel is subjected to selective induction by controlling laser parameters and the scanning path to form the modified layer; a pre-embedded modified layer strategy for energy shielding is adopted, so that graphitization damage inside the diamond body is avoided, the intrinsic characteristics of the single-crystal diamond are retained, and the stringent requirements of high-power optical devices, ultra-high heat flux density heat sinks and other applications on material performance can be met; and the integrated processing of a pre-modified layer and a microchannel body is directly completed by precisely programming the laser focus position and the scanning path, thereby simplifying the process flow and being suitable for the rapid preparation of complex microchannel structures.

Further, the ultraviolet picosecond laser processing system is used, the laser parameters (such as pulse energy, repetition frequency, and focus position) are adjusted, layer-by-layer scanning and processing are performed along the preset path, and during the process of increasing the depth of the microchannel, the pre-embedded modified layer forms a physical barrier by locally absorbing laser energy, thereby blocking the influence of the laser on the lower area that is not required to be processed, and ensuring that the bottom of the microchannel is in an unmodified state all the time.

Further, all the above steps are performed in a dust-free laboratory, and sample transfer is performed using a sealed vacuum tank.

Further, the laser focus is accurately focused on the preset depth position of the target microchannel, and the focus offset compensation is performed. Due to the large difference in the refractive index between the diamond and the air, the phase difference between the interfaces of the two media will cause the actual focus to shift downward. After the focus offset is calculated, compensation is performed through the actual moving distance of a Z-axis displacement stage, thereby ensuring that the laser is focused on the target position.

Further, it is only necessary to subject the bottom area of the side wall of the microchannel to selective induction to pre-embed the modified area. During the forming process of the microchannel, the bottom of the microchannel is uneven and rough, and the laser can not enter the diamond through the bottom of the microchannel so as not to perform modification. The reason for the modification outside the target microchannel area is that: at two edges (that is, the side wall of the microchannel) of the processing path, one part of the laser beam enters the diamond after being refracted by the upper surface of the diamond wafer, and due to the large refractive index difference between the air and the diamond, this part of the laser beam is focused below the preset depth position of the target microchannel and exceeds the modification threshold, thereby generating the internal modification that is not required and cannot be removed.

Further, during the induced processing of the pre-modified layer, the parameters of the processing system adopt the parameters of the pre-modified stage: a small single-pulse energy (<3 µJ) is used to avoid cracks caused by excessive graphitization inside, and the scanning speed is required to be matched with the laser repetition frequency so as to ensure that the equivalent pulse density is greater than 10/µm (this value is obtained by dividing the laser repetition frequency by the scanning speed); and a scanning path used is a periodic jump scanning path, and a transverse interval is 0.2 to 1 times a diameter of the laser focus, thereby ensuring that the modified layer continuously covers the bottom area of the side wall.

Further, when the microchannel body is processed, the parameters of the processing system parameters adopt the parameters of the main processing stage: a large single-pulse energy is used to efficiently remove the diamond material (the higher the single-pulse energy, the higher the removal rate), and the scanning speed is required to be matched with the laser repetition frequency so as to ensure that the equivalent pulse density is greater than 50/µm; and a scanning path used is a periodic jump scanning path, a transverse interval is 0.2 to 1 times a diameter of the laser focus so as to ensure the efficient removal of the material, a longitudinal interval is 10 µm to 30 µm (required to be matched with the single-pulse energy), a number of scanning lines in an XY plane is matched with a width of the microchannel, a number of longitudinal scanning lines is matched with a depth and the longitudinal interval, and the focus is slightly lower than the bottom of the microchannel in the forming process to maintain the efficiency removal of the material.

Further, the light absorption coefficient of the pre-embedded modified layer (amorphous carbon) is much higher than that of the single-crystal diamond, so that laser energy can be significantly absorbed and an isolation area can be formed, thereby enabling the laser energy density and temperature of the unmodified diamond area below to be less than a graphitization threshold of the diamond. Since the position of the pre-embedded modified area is at or above the depth of the target microchannel, the pre-embedded modified area will also be removed when layer-by-layer scanning is performed to the target depth of the microchannel, and an internal modified area is not present in the finally obtained single-crystal diamond wafer with the microchannel manufacturing completed.

Further, the high-temperature oxidation requires vacuumizing a tubular furnace, then introducing oxygen and maintaining it for several hours at the high temperature to completely remove the modified layer on the surface of the microchannel, and avoiding the damage of excessive oxidation to the single-crystal diamond body.

### BRIEF DESCRIPTION OF THE DRAWINGS

FIG. 1 is a schematic structural diagram of an ultraviolet picosecond laser processing system according to an embodiment of the present disclosure;

FIG. 2 is a schematic diagram of a pre-embedded modified layer strategy for energy shielding according to an embodiment of the present disclosure;

FIG. 3 is a transmission microscope photograph of modified areas generated at different heights according to an embodiment of the present disclosure;

FIG. 4 is a transmission microscope photograph of a microchannel without an internal modified area according to an embodiment of the present disclosure;

FIG. 5 is a transmission microscope photograph of a microchannel obtained without the pre-embedded modification step according to an embodiment of the present disclosure; and

FIG. 6 is a Raman spectrogram of a side wall of a microchannel oxidized at a high temperature according to an embodiment of the present disclosure.

### DETAILED DESCRIPTION OF THE EMBODIMENTS

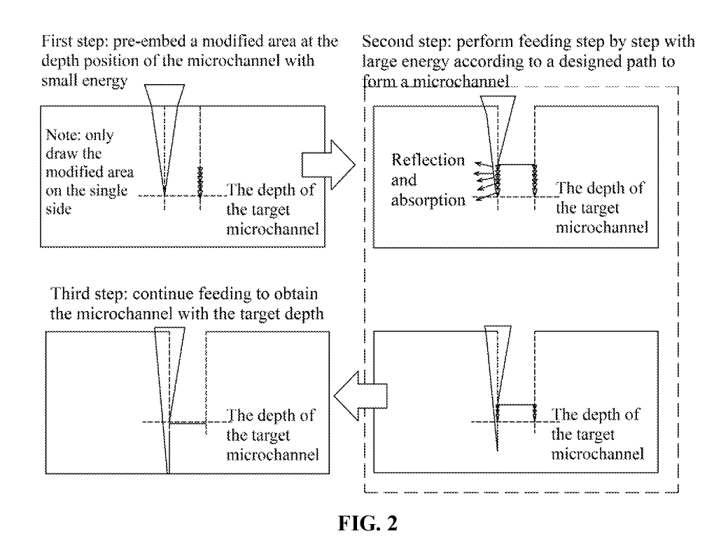

The technical concept of the present disclosure lies in that: based on the pre-embedded modified layer strategy for energy shielding, before the processing of the microchannel, a bottom modified area of a side wall is induced at a target depth in advance to form a laser energy shielding area, thereby avoiding lattice damage in other areas inside diamond during the processing; and finally, high-temperature oxidation is performed to remove the modified area in a microchannel, thereby achieving the efficiency formation of a microchannel without a modified area. By the pre-embedded modified layer strategy for energy shielding, the depth and shape of the microchannel are accurately controlled while avoiding lattice damage, which breaks through the performance limit of the prior art and provides critical manufacturing support for the application of the single-crystal diamond in the field of high-added value. Referring to FIG. 2, the specific innovation points lie in that:
1. Pre-embedded modified layer strategy for energy shielding: by inducing the bottom of the side wall of the microchannel to generate the pre-modified layer that absorbs and isolates the laser energy, the focusing of the laser in the non-processing area is obstructed, thus avoiding the modification of the non-processing area.
2. Self-removal mechanism of pre-modified layer: through the accurate positioning of the internal focus of the diamond, the pre-modified layer is induced to grow upward from the bottom of the target microchannel, so in the formation process of the microchannel, the pre-modified layer will be removed gradually during the processing of the microchannel body. To make the objects, technical solutions, and advantages of the present disclosure clearer, the present disclosure will be further described below in detail with reference to the drawings and examples. The target of this specific embodiment is to process a microchannel with a length of 10 mm, a width of 40 µm to 500 µm, and a depth of 200 µm to 1500 µm.

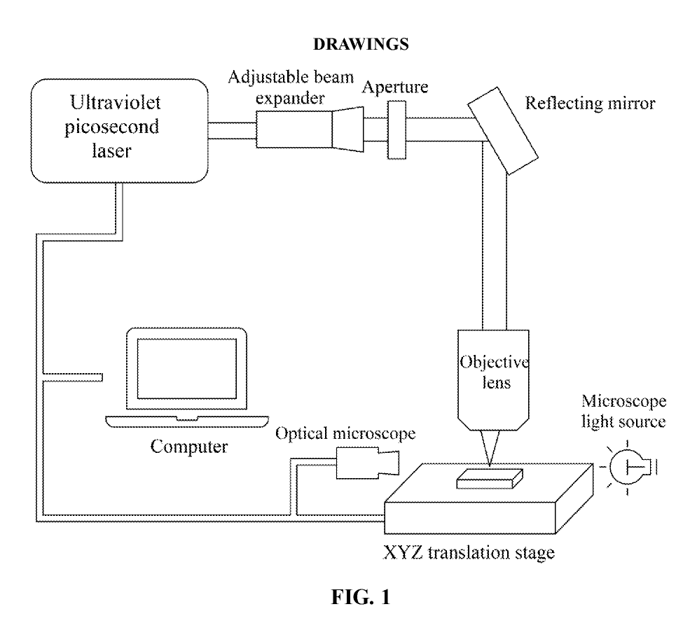

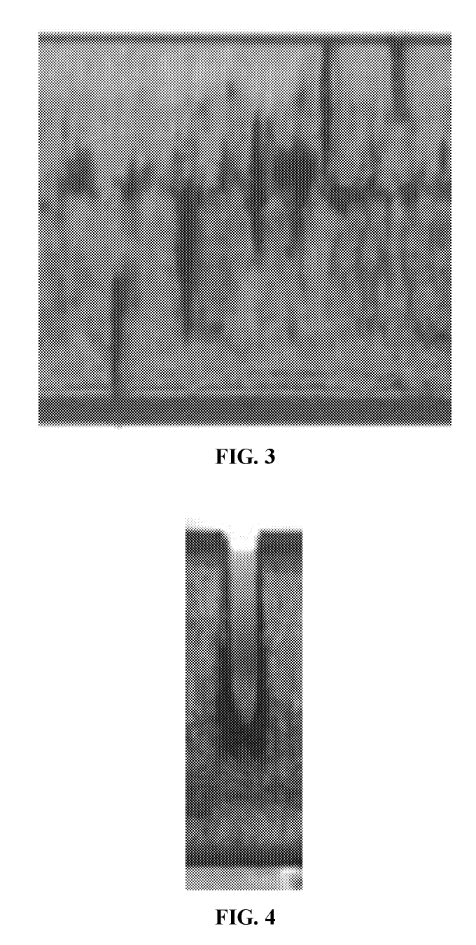

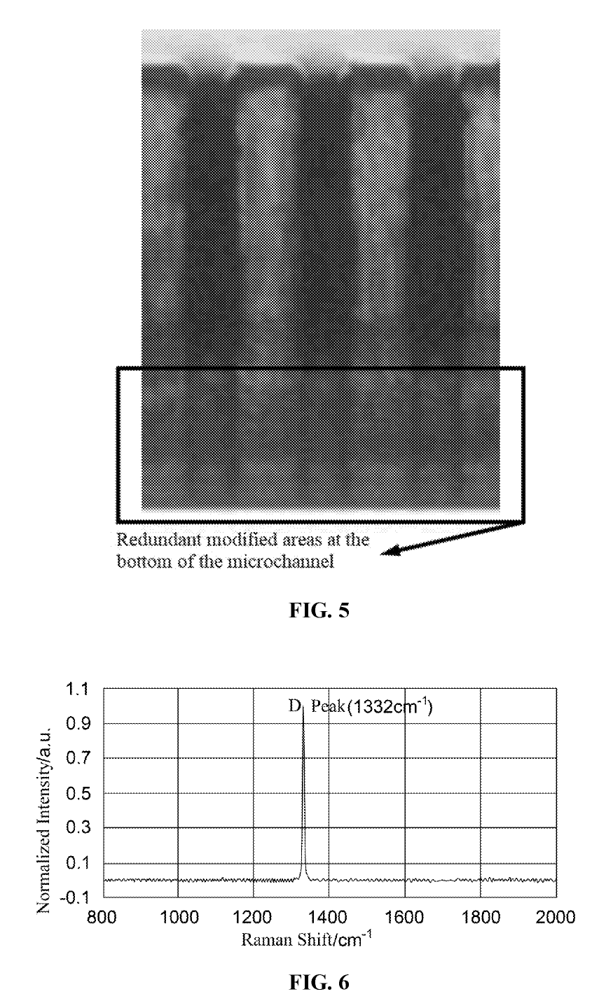

The technical solutions of the embodiments of the present disclosure are described clearly and completely below with reference to the drawings in the examples of the present disclosure. Apparently, the described examples are merely a part rather than all of the examples of the present disclosure. All other examples obtained by those of ordinary skill in the art, based on the examples of the present disclosure, without creative efforts, shall fall within the scope of the present disclosure.
1. An ultraviolet picosecond laser processing system with a laser central wavelength of 355 nm is used. As shown in FIG. 1, an ultraviolet picosecond laser processing system is arranged with an ultraviolet picosecond laser, a beam expander, an aperture, two reflecting mirrors, a two-dimensional scanning galvanometer, an F-θ field lens, and a three-axis motion platform sequentially along an optical path; and a laser repetition frequency is fixed at 100 kHz, a variable-magnification beam expander is used to adjust a diameter of a light beam to 6 mm and reduce a divergence angle (<1 mrad), and a focusing objective lens and an XYZ motion system are configured.
2. A single-crystal diamond is ultrasonically cleaned for 5 minutes each in a constant-temperature dust-free laboratory with analytically pure acetone, anhydrous ethanol, and deionized water sequentially, and a surface thereof is blow-dried with nitrogen.
3. A double-sided precision polished silicon wafer with a thickness of 560 µm is placed on the laser processing system to find focus space coordinates by enabling the laser to draw short straight lines at different Z-axis heights, and the Z-axis interval used is required to be less than or equal to 5 µm. After completion, a thickness of a single-crystal diamond wafer is measured with a micrometer, thickness differences with the silicon wafers are calculated, a single-crystal diamond wafer to be processed is clamped, and the Z axis is adjusted to enable a focus on an upper surface of the single-crystal diamond wafer to be processed.
4. The ultraviolet picosecond laser processing system is used, and a power factor is adjusted to an average power of 0.3 W of a focused laser measured by a laser power meter, which corresponds to 3 µJ single-pulse energy at a repetition frequency of 100 kHz. A Z-axis displacement stage is controlled to move downward by 180 µm, so that the laser focus is located at a depth of a target microchannel, that is, 300 µm. Two S-shaped scanning paths are arranged at two edge positions (that is, two side wall positions) of the target microchannel, with a scanning speed of 1 mm/s, a length of 10 mm, and a transverse interval of 5 µm. After the arrangement is completed, the laser is controlled to scan along the paths so as to generate a pre-embedded modified area with a height of about 200 µm at a target depth or above. FIG. 3 shows the modified areas generated at different heights in the diamond.
5. An average power of the ultraviolet picosecond laser processing system is adjusted to 1.0 W, which corresponds to 10 µJ single-pulse energy. The height of the Z axis is adjusted again, so that the position of the laser focus is located on the upper surface of the single-crystal diamond wafer. An S-shaped scanning path is arranged at the position of the target microchannel according to structural parameters of the target microchannel, with a scanning speed of 1 mm/s, a length of 10 mm, a transverse interval of 5 µm, a number of transverse arrays being 9, a longitudinal interval of 20 µm, and a number of longitudinal arrays being 14. After the arrangement is completed, the laser is controlled to scan along the path, thereby achieving the processing of a microchannel with a length of 10 mm, a width of 40 µm to 500 µm, and a depth of 200 µm to 1500 µm. It can be seen from FIG. 4 that, by a transmission optical microscope, there is no modified area at the lower area of the target microchannel. For comparison, FIG. 5 shows a microchannel not subjected to pre-embedded modified area processing in step 4, and an obvious linear modified area can be seen at the bottom.
6. A resulting laser-processed single-crystal diamond wafer is placed in a high-temperature-resistant aluminum oxide crucible and into a quartz tube of a tubular furnace. After ensuring that the tubular furnace is tightly sealed, the quartz tube is vacuumized by a vacuum pump to a relative pressure of -0.1 MPa. Inflating valves of an oxygen tank and the tubular furnace are opened respectively, the oxygen flow is controlled by a gas flowmeter, and the valves are closed after the oxygen pressure in the quartz tube reached -0.01 MPa. The heating time and temperature of the tubular furnace are adjusted, so that the single-crystal diamond is heated at 550°C for 24 hours in an oxygen atmosphere.
7. A resulting processed single-crystal diamond wafer is subjected to high-temperature oxidation and then taken out, and the side wall of the microchannel is measured by a Raman Spectrometer. It is found that only one peak position is present at 1330cm⁻¹ (that is, D peak), as shown in FIG. 6, indicating that a graphitized phase change component is not present on the side wall of the microchannel.

The above contents are only for illustrating the technical idea of the present disclosure and cannot be used to limit the scope of the present disclosure. Any changes made based on the technical solutions according to the technical idea proposed by the present disclosure fall within the scope of the claims of the present disclosure.

### Example 1

A diamond microchannel without an internal modified structure was manufactured by a specific method consisting of the following steps:
1. An ultraviolet picosecond laser processing system with a laser central wavelength of 355 nm was used. As shown in FIG. 1, an ultraviolet picosecond laser processing system was arranged with an ultraviolet picosecond laser, a beam expander, an aperture, two reflecting mirrors, a two-dimensional scanning galvanometer, an F-θ field lens, and a three-axis motion platform sequentially along an optical path; and a laser repetition frequency was fixed at 100 kHz, a variable-magnification beam expander was used to adjust a diameter of a light beam to 6 mm and reduce a divergence angle (<1 mrad), and a focusing objective lens and an XYZ motion system motion system were configured.
2. A single-crystal diamond was ultrasonically cleaned for 5 minutes each in a constant-temperature dust-free laboratory with analytically pure acetone, anhydrous ethanol, and deionized water sequentially, and a surface thereof was blow-dried with nitrogen.
3. A double-sided precision polished silicon wafer with a thickness of 560 µm was placed on the laser processing system to find focus space coordinates by enabling the laser to draw short straight lines at different Z-axis heights, and the Z-axis interval used was required to be less than or equal to 5 µm. After completion, a thickness of a single-crystal diamond wafer was measured with a micrometer, thickness differences with the silicon wafers were calculated, a single-crystal diamond wafer to be processed was clamped, and the Z axis was adjusted to enable a focus on an upper surface of the single-crystal diamond wafer to be processed.
4. The ultraviolet picosecond laser processing system was used, and a power factor was adjusted to an average power of 0.3 W of a focused laser measured by a laser power meter, which corresponds to 3 µJ single-pulse energy at a repetition frequency of 100 kHz. A Z-axis displacement stage was controlled to move downward by 180 µm, so that the laser focus was located at a depth of a target microchannel, that is, 300 µm. Two S-shaped scanning paths were arranged at two edge positions (that is, two side wall positions) of the target microchannel, with a scanning speed of 1 mm/s, a length of 10 mm, and a transverse interval of 5 µm. After the arrangement was completed, the laser was controlled to scan along the paths so as to generate a pre-embedded modified area with a height of about 200 µm at a target depth or above. FIG. 3 shows the modified areas generated at different heights in the diamond.
5. An average power of the ultraviolet picosecond laser processing system was adjusted to 1.0 W, which corresponds to 10 µJ single-pulse energy. The height of the Z axis was adjusted again, so that the position of the laser focus was located on the upper surface of the single-crystal diamond wafer. An S-shaped scanning path was arranged at the position of the target microchannel according to structural parameters of the target microchannel, with a scanning speed of 1 mm/s, a length of 10 mm, a transverse interval of 5 µm, a number of transverse arrays being 7, a longitudinal interval of 20 µm, and a number of longitudinal arrays being 9. After the arrangement was completed, the laser was controlled to scan along the path, thereby achieving the processing of a microchannel with a length of 10 mm, a width of 40 µm, and a depth of 200 µm. It can be seen from FIG. 4 that, by a transmission optical microscope, there is no modified area at the lower area of the target microchannel. For comparison, FIG. 5 shows a microchannel not subjected to pre-embedded modified area processing in step 4, and an obvious linear modified area can be seen at the bottom.
6. A resulting laser-processed single-crystal diamond wafer was placed in a high-temperature-resistant aluminum oxide crucible and into a quartz tube of a tubular furnace. After ensuring that the tubular furnace was tightly sealed, the quartz tube was vacuumized by a vacuum pump to a relative pressure of -0.1 MPa. Inflating valves of an oxygen tank and the tubular furnace were opened respectively, the oxygen flow was controlled by a gas flowmeter, and the valves were closed after the oxygen pressure in the quartz tube reached -0.01 MPa. The heating time and temperature of the tubular furnace were adjusted, so that the single-crystal diamond was heated at 550°C for 24 hours in an oxygen atmosphere.
7. A resulting processed single-crystal diamond wafer was subjected to high-temperature oxidation and then taken out, and the side wall of the microchannel was measured by a Raman Spectrometer. It was found that only one peak position was present at 1330 cm⁻¹ (that is, D peak), as shown in FIG. 6, indicating that a graphitized phase change component is not present on the side wall of the microchannel.

### Example 2

A diamond microchannel without an internal modified structure was manufactured by a specific method consisting of the following steps:
1. An ultraviolet picosecond laser processing system with a laser central wavelength of 355 nm was used. As shown in FIG. 1, an ultraviolet picosecond laser processing system was arranged with an ultraviolet picosecond laser, a beam expander, an aperture, two reflecting mirrors, a two-dimensional scanning galvanometer, an F-θ field lens, and a three-axis motion platform sequentially along an optical path; and a laser repetition frequency was fixed at 100 kHz, a variable-magnification beam expander was used to adjust a diameter of a light beam to 6 mm and reduce a divergence angle (<1 mrad), and a focusing objective lens and an XYZ motion system were configured.
2. A single-crystal diamond was ultrasonically cleaned for 5 minutes each in a constant-temperature dust-free laboratory with analytically pure acetone, anhydrous ethanol, and deionized water sequentially, and a surface thereof was blow-dried with nitrogen.
3. A double-sided precision polished silicon wafer with a thickness of 560 µm was placed on the laser processing system to find focus space coordinates by enabling the laser to draw short straight lines at different Z-axis heights, and the Z-axis interval used was required to be less than or equal to 5 µm. After completion, a thickness of a single-crystal diamond wafer was measured with a micrometer, thickness differences with the silicon wafers were calculated, a single-crystal diamond wafer to be processed was clamped, and the Z axis was adjusted to enable a focus on an upper surface of the single-crystal diamond wafer to be processed.
4. The ultraviolet picosecond laser processing system was used, and a power factor was adjusted to an average power of 0.3 W of a focused laser measured by a laser power meter, which corresponds to 3 µJ single-pulse energy at a repetition frequency of 100 kHz. A Z-axis displacement stage was controlled to move downward by 180 µm, so that the laser focus was located at a depth of a target microchannel, that is, 300 µm. Two S-shaped scanning paths were arranged at two edge positions (that is, two side wall positions) of the target microchannel, with a scanning speed of 1 mm/s, a length of 10 mm, and a transverse interval of 5 µm. After the arrangement was completed, the laser was controlled to scan along the paths so as to generate a pre-embedded modified area with a height of about 200 µm at a target depth or above. FIG. 3 shows the modified areas generated at different heights in the diamond.
5. An average power of the ultraviolet picosecond laser processing system was adjusted to 1.0 W, which corresponds to 10 µJ single-pulse energy. The height of the Z axis was adjusted again, so that the position of the laser focus was located on the upper surface of the single-crystal diamond wafer. An S-shaped scanning path was arranged at the position of the target microchannel according to structural parameters of the target microchannel, with a scanning speed of 1 mm/s, a length of 10 mm, a transverse interval of 5 µm, a number of transverse arrays being 19, a longitudinal interval of 20 µm, and a number of longitudinal arrays being 49. After the arrangement was completed, the laser was controlled to scan along the path, thereby achieving the processing of a microchannel with a length of 10 mm, a width of 100 µm, and a depth of 1000 µm. It can be seen from FIG. 4 that, by a transmission optical microscope, there is no modified area at the lower area of the target microchannel. For comparison, FIG. 5 shows a microchannel not subjected to pre-embedded modified area processing in step 4, and an obvious linear modified area can be seen at the bottom.
6. A resulting laser-processed single-crystal diamond wafer was placed in a high-temperature-resistant aluminum oxide crucible and into a quartz tube of a tubular furnace. After ensuring that the tubular furnace was tightly sealed, the quartz tube was vacuumized by a vacuum pump to a relative pressure of -0.1 MPa. Inflating valves of an oxygen tank and the tubular furnace were opened respectively, the oxygen flow was controlled by a gas flowmeter, and the valves were closed after the oxygen pressure in the quartz tube reached -0.01 MPa. The heating time and temperature of the tubular furnace were adjusted, so that the single-crystal diamond was heated at 550°C for 24 hours in an oxygen atmosphere.
7. A resulting processed single-crystal diamond wafer was subjected to high-temperature oxidation and then taken out, and the side wall of the microchannel was measured by a Raman Spectrometer. It was found that only one peak position was present at 1330cm⁻¹ (that is, D peak), as shown in FIG. 6, indicating that a graphitized phase change component is not present on the side wall of the microchannel.

### Example 3

A diamond microchannel without an internal modified structure was manufactured by a specific method consisting of the following steps:
1. An ultraviolet picosecond laser processing system with a laser central wavelength of 355 nm was used. As shown in FIG. 1, an ultraviolet picosecond laser processing system was arranged with an ultraviolet picosecond laser, a beam expander, an aperture, two reflecting mirrors, a two-dimensional scanning galvanometer, an F-? field lens, and a three-axis motion platform sequentially along an optical path; and a laser repetition frequency was fixed at 100 kHz, a variable-magnification beam expander was used to adjust a diameter of a light beam to 6 mm and reduce a divergence angle (<1 mrad), and a focusing objective lens and an XYZ motion system were configured.
2. A single-crystal diamond was ultrasonically cleaned for 5 minutes each in a constant-temperature dust-free laboratory with analytically pure acetone, anhydrous ethanol, and deionized water sequentially, and a surface thereof was blow-dried with nitrogen.
3. A double-sided precision polished silicon wafer with a thickness of 560 µm was placed on the laser processing system to find focus space coordinates by enabling the laser to draw short straight lines at different Z-axis heights, and the Z-axis interval used was required to be less than or equal to 5 µm. After completion, a thickness of a single-crystal diamond wafer was measured with a micrometer, thickness differences with the silicon wafers were calculated, a single-crystal diamond wafer to be processed was clamped, and the Z axis was adjusted to enable a focus on an upper surface of the single-crystal diamond wafer to be processed.
4. The ultraviolet picosecond laser processing system was used, and a power factor was adjusted to an average power of 0.3 W of a focused laser measured by a laser power meter, which corresponds to 3 µJ single-pulse energy at a repetition frequency of 100 kHz. A Z-axis displacement stage was controlled to move downward by 180 µm, so that the laser focus was located at a depth of a target microchannel, that is, 300 µm. Two S-shaped scanning paths were arranged at two edge positions (that is, two side wall positions) of the target microchannel, with a scanning speed of 1 mm/s, a length of 10 mm, and a transverse interval of 5 µm. After the arrangement was completed, the laser was controlled to scan along the paths so as to generate a pre-embedded modified area with a height of about 200 µm at a target depth or above. FIG. 3 shows the modified areas generated at different heights in the diamond.
5. An average power of the ultraviolet picosecond laser processing system was adjusted to 1.0 W, which corresponds to 10 µJ single-pulse energy. The height of the Z axis was adjusted again, so that the position of the laser focus was located on the upper surface of the single-crystal diamond wafer. An S-shaped scanning path was arranged at the position of the target microchannel according to structural parameters of the target microchannel, with a scanning speed of 1 mm/s, a length of 10 mm, a transverse interval of 5 µm, a number of transverse arrays being 99, a longitudinal interval of 20 µm, and a number of longitudinal arrays being 74. After the arrangement was completed, the laser was controlled to scan along the path, thereby achieving the processing of a microchannel with a length of 10 mm, a width of 500 µm, and a depth of 1500 µm. It can be seen from FIG. 4 that, by a transmission optical microscope, there is no modified area at the lower area of the target microchannel. For comparison, FIG. 5 shows a microchannel not subjected to pre-embedded modified area processing in step 4, and an obvious linear modified area can be seen at the bottom.
6. A resulting laser-processed single-crystal diamond wafer was placed in a high-temperature-resistant aluminum oxide crucible and into a quartz tube of a tubular furnace. After ensuring that the tubular furnace was tightly sealed, the quartz tube was vacuumized by a vacuum pump to a relative pressure of -0.1 MPa. Inflating valves of an oxygen tank and the tubular furnace were opened respectively, the oxygen flow was controlled by a gas flowmeter, and the valves were closed after the oxygen pressure in the quartz tube reached -0.01 MPa. The heating time and temperature of the tubular furnace were adjusted, so that the single-crystal diamond was heated at 550°C for 24 hours in an oxygen atmosphere.
7. A resulting processed single-crystal diamond wafer was subjected to high-temperature oxidation and then taken out, and the side wall of the microchannel was measured by a Raman Spectrometer. It was found that only one peak position was present at 1330cm⁻¹ (that is, D peak), as shown in FIG. 6, indicating that a graphitized phase change component is not present on the side wall of the microchannel.

The above contents are only for illustrating the technical idea of the present disclosure and cannot be used to limit the scope of the present disclosure. Any changes made based on the technical solutions according to the technical idea proposed by the present disclosure fall within the scope of the claims of the present disclosure.

What is claimed is:

1. A method for manufacturing a diamond microchannel without an internal modified structure, comprising:
focusing a laser focus on a preset depth position of a microchannel by using an ultraviolet picosecond laser processing system, and subjecting a bottom area of a side wall of the microchannel to selective induction to form a modified layer;
subjecting the microchannel to layer-by-layer scanning, and processing and forming along a preset microchannel path; and
subjecting a resulting processed and formed microchannel to high-temperature oxidation to remove the modified layer in the microchannel, and cleaning and drying to obtain the diamond microchannel without the internal modified structure.

2. The method for manufacturing the diamond microchannel without the internal modified structure of claim 1, wherein a laser in the ultraviolet picosecond laser processing system has a central wavelength of 355 nm and a pulse width of 10 ps (picosecond).

3. The method for manufacturing the diamond microchannel without the internal modified structure of claim 1, wherein the ultraviolet picosecond laser processing system is turned on and warmed up, and a position of the laser focus is accurately calibrated with a silicon wafer having a uniform thickness.

4. The method for manufacturing the diamond microchannel without the internal modified structure of claim 1, wherein a single-crystal diamond wafer is ultrasonically cleaned with acetone, anhydrous ethanol, and deionized water, and finally dried.

5. The method for manufacturing the diamond microchannel without the internal modified structure of claim 1, wherein an error between a focusing position of the laser focus and a position of an actual focus is within ± 5 µm.

6. The method for manufacturing the diamond microchannel without the internal modified structure of claim 1, wherein the method further comprises conducting a focus offset compensation when the laser focus focuses on the preset depth position of the microchannel.

7. The method for manufacturing the diamond microchannel without the internal modified structure of claim 1, wherein a small single-pulse energy is used, and a scanning speed is matched with a laser repetition frequency, so that an equivalent pulse density is greater than 10/µm; and a scanning path is a periodic jump scanning path, and a transverse interval is 0.2 to 1 times a diameter of the laser focus.

8. The method for manufacturing the diamond microchannel without the internal modified structure of claim 1, wherein a large single-pulse energy is used, and a scanning speed is matched with a laser repetition frequency, so that an equivalent pulse density is greater than 50/µm; and a scanning path is a periodic jump scanning path, a transverse interval is 0.2 to 1 times a diameter of the laser focus, a longitudinal interval is in a range of 10 µm to 30 µm, a number of scanning lines in an XY plane is matched with a width of the microchannel, and a number of longitudinal scanning lines is matched with a depth and the longitudinal interval.

9. The method for manufacturing the diamond microchannel without the internal modified structure of claim 1, wherein subjecting the resulting processed and formed microchannel to high-temperature oxidation is conducted by vacuumizing a treatment environment, then filling with oxygen, and then conducting heating oxidation.

10. A diamond microchannel without an internal modified structure, obtained by the method of claim 1.
